(19) United States
(12) Patent Application Publication
(10) Pub. No.: US 2008/0246505 A1
(43) Pub. Date: Oct. 9, 2008

(54) SEMICONDUCTOR DEVICE TEST SYSTEM AND METHOD

(75) Inventors: Markus Kollwitz, Neubiberg (DE); Carsten Ohlhoff, Dresden (DE)

Correspondence Address: DICKE, BILLIG & CZAJA, FIFTH STREET TOWERS, 100 SOUTH FIFTH STREET, SUITE 2250, MINNEAPOLIS, MN, 55402, US

(73) Assignee: QIMONDA AG, Muenchen (DE)

(21) Appl. No.: 12/098,040

(22) Filed: Apr. 4, 2008

(30) Foreign Application Priority Data
Apr. 5, 2007 (DE) 10 2007 016 622.4

(51) Int. Cl. G01R 31/26

(52) U.S. Cl. 324/765

(57) ABSTRACT

A semiconductor device test method and system. One embodiment provides a method for testing semiconductor devices forming a group of semiconductor devices to be tested. For addressing or selection of one of the semiconductor devices of the group, at least two different signals are supplied to the respective semiconductor device to be addressed or selected via at least two different semiconductor device connections.

### CROSS-REFERENCE TO RELATED APPLICATIONS

This Utility Patent Application claims priority to German Patent Application No. DE 10 2007 016 622.4 filed on Apr. 5, 2007, which is incorporated herein by reference.

### BACKGROUND

The invention relates to a semiconductor device test system, to a method for testing semiconductor devices, to a semiconductor device test device, and to a semiconductor device test card.

Semiconductor devices are, in the finished and/or in the semi-finished state, subject to comprehensive tests.

The signals required for testing the finished or semi-finished semiconductor devices, that are still available on a corresponding wafer, may, for instance, be generated by a test device that is connected with a corresponding semiconductor device test card (probe card), and be input in the respective semiconductor devices by using corresponding, for instance, needle-shaped connections provided at the test card (e.g., via corresponding semiconductor device pads provided at the surface of the wafer).

The signals output by the semiconductor devices in reaction to the input test signals are tapped by corresponding, e.g., needle-shaped probe card connections, and are transmitted to the test device where an evaluation of the corresponding signals can take place.

In order to be able to test a preferably large number of semiconductor devices in parallel or simultaneously with one and the same test device, a corresponding test signal output by the test device may, simultaneously, be transmitted to a plurality of, e.g., n=4 or 8, etc. different semiconductor devices forming a test group.

Thus, it is, for instance, possible to test, by using test signals provided at k different test device connections (i.e. with k different test channels), n×k, e.g., 4×k (or 8×k, etc.) different semiconductor devices simultaneously, and thus it is possible to save test channels.

With particular test methods, e.g., with soft trimming methods used for setting internal voltages in the semiconductor device, etc., it is not possible to use one and the same test channel simultaneously for a plurality of different, in particular for all semiconductor devices comprised in the respective test group.

Instead, the corresponding test method, e.g., the respective soft trimming method, has to be performed separately for every semiconductor device (in particular for every semiconductor device comprised in the corresponding test group) (i.e. chip-individually).

For selecting or for addressing the corresponding semiconductor device, a number of separate CS connections or CS channels (chip select or semiconductor device select channels), corresponding, for instance, to the number of semiconductor devices comprised in the respective test group, may be provided, wherein a corresponding CS signal may be output by the respective test device at the respective CS connections, separately for every semiconductor device comprised in the corresponding test group.

Thus, it can be signalized to a particular semiconductor device connected to the respective CS channel whether the signals present at a, shared, test channel are to be valid for the very respective semiconductor device (e.g., if a corresponding test method is just to be performed simultaneously for a plurality of semiconductor devices, or e.g., for the corresponding semiconductor device a soft trimming method, etc.), or not (for instance, if, by making use of the shared test channel, a soft trimming method is just to be performed for another semiconductor device comprised in the test group, etc.).

The relatively high number of separate CS channels or CS connections required for addressing the respectively concerned semiconductor device is, however, of disadvantage here.

For these and other reasons, there is a need for the present invention.

### BRIEF DESCRIPTION OF THE DRAWINGS

The accompanying drawings are included to provide a further understanding of embodiments and are incorporated in and constitute a part of this specification. The drawings illustrate embodiments and together with the description serve to explain principles of embodiments. Other embodiments and many of the intended advantages of embodiments will be readily appreciated as they become better understood by reference to the following detailed description. The elements of the drawings are not necessarily to scale relative to each other. Like reference numerals designate corresponding similar parts.

FIG. 1 illustrates one embodiment of a schematic representation of the structure of a semiconductor device test system.

FIG. 2 illustrates a schematic representation of a section of the semiconductor device test card illustrated in FIG. 1, of a section of the semiconductor device test device illustrated in FIG. 1, and of a section of the wafer illustrated in FIG. 1, which are designed and equipped such that a device addressing or selection method according to one embodiment can be performed.

FIG. 3a illustrates a schematic representation of a plurality of semiconductor devices and of test channels connected thereto, for illustrating a conventional device addressing or selection method.

FIG. 3b illustrates a schematic representation of a plurality of semiconductor devices and of test channels connected thereto for illustrating a device addressing or selection method according to one embodiment.

FIG. 3c illustrates a schematic representation of a plurality of semiconductor devices and of test channels connected thereto for illustrating a device addressing or selection method according to one embodiment.

FIG. 3d illustrates a schematic representation of a plurality of semiconductor devices and of test channels connected thereto for illustrating a device addressing or selection method according to one embodiment.

### DETAILED DESCRIPTION

In the following Detailed Description, reference is made to the accompanying drawings, which form a part hereof, and in which is shown by way of illustration specific embodiments in which the invention may be practiced. In this regard, directional terminology, such as “top,” “bottom,” “front,” “back,” “leading,” “trailing,” etc., is used with reference to the orientation of the Figure(s) being described. Because components of embodiments can be positioned in a number of different orientations, the directional terminology is used for purposes of illustration and is in no way limiting. It is to be understood that other embodiments may be utilized and structural or logical changes may be made without departing from the scope of the present invention. The following detailed description, therefore, is not to be taken in a limiting sense, and the scope of the present invention is defined by the appended claims.

It is to be understood that the features of the various exemplary embodiments described herein may be combined with each other, unless specifically noted otherwise.

In accordance with one embodiment, there is provided a method for testing semiconductor devices forming a group of semiconductor devices to be tested, wherein, for addressing or selecting one of the semiconductor devices of the group, at least two different signals are supplied to the respective semiconductor device to be addressed or selected via at least two different semiconductor device connections.

The method may, for instance, include activating a first and a third signal if a first one of the semiconductor devices is to be addressed or selected, activating the first and a fourth signal if a third one of the semiconductor devices is to be addressed or selected, activating a second and the third signal if a second one of the semiconductor devices is to be addressed or selected, and activating the second and the fourth signal if a fourth one of the semiconductor devices is to be addressed or selected.

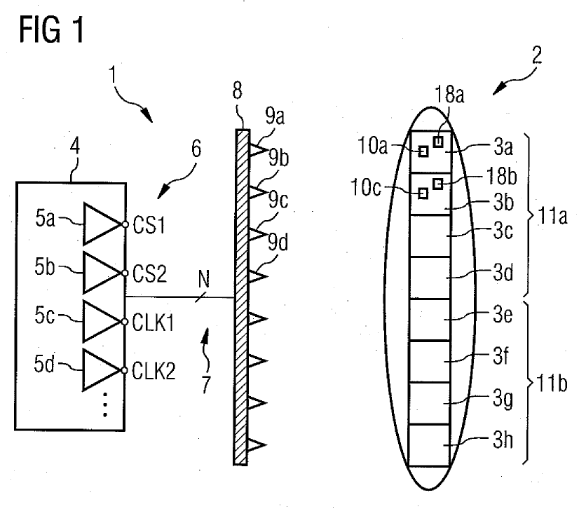

FIG. 1 illustrates a schematic representation of the structure of a semiconductor device test system 1 used with one embodiment.

It serves, for instance, to test semiconductor devices 3a, 3b, 3c, 3d, 3e, 3f, 3g, 3h manufactured on a silicon disc or a wafer 2 (or semiconductor devices 3a, 3b, 3c, 3d, 3e, 3f, 3g, 3h arranged, jointly, on the wafer 2 and being in a finished or semi-finished state). In one embodiment, the semiconductor devices 3a, 3b, 3c, 3d, 3e, 3f, 3g, 3h may also have been separated from each other before, i.e. the wafer 2 may have been sawn apart, or scratched and broken before, and/or the semiconductor devices 3a, 3b, 3c, 3d, 3e, 3f, 3g, 3h may already have been incorporated in corresponding, separate semiconductor devices.

The semiconductor devices 3a, 3b, 3c, 3d, 3e, 3f, 3g, 3h may be, finished or semi-finished, or partially finished, semiconductor devices, e.g., corresponding, integrated (analog or digital) circuits, e.g., computing circuits, or micro processors, or semiconductor memory devices such as, for instance, functional memory devices (PLAs, PALs, etc.), or table memory devices (e.g., ROMs or RAMS), in one embodiment SRAMs or DRAMs (here e.g., DRAMs (Dynamic Random Access Memories or dynamic write-read memories) with double data rate (DDR-DRAMs=Double Data Rate, DRAMs)), etc.

The test input signals required for testing the semiconductor devices 3a, 3b, 3c, 3d, 3e, 3f, 3g, 3h or for performing corresponding test methods are generated by a test device 4, and, by using corresponding signal driver devices 5a, 5b, 5c, 5d, output at corresponding connections 6 of the test device 4.

As is further illustrated in FIG. 1, the connections 6 of the test device 4 may (via corresponding lines, here: a number N of lines 7), be connected to corresponding connections of a semiconductor device test card 8 or probe card 8 which may, via corresponding probe card contacts or contact needles 9a, 9b, 9c, 9d that are in connection with the probe card connections, be connected to corresponding (test) connections 10a, 18a, 10c, 18b provided on the semiconductor devices 3a, 3b, 3c, 3d (e.g., to corresponding semiconductor device pads 10a, 18a, 10c, 18b provided at the surface of the wafer). In one embodiment, the use of a probe card may also be waived, or, in one embodiment, for instance, in the above-mentioned alternative embodiment, the connections 6 of the test device 4 may also be connected to corresponding semiconductor device package pins, etc.

Instead of the above-mentioned contact needles 9a, 9b, 9c, 9d, contacts of any other design may also be used as probe card contacts, e.g., instead of needle-shaped contacts, also corresponding pyramidal contacts, conical contacts, rectangular contacts, round or oval contacts, etc.

The test input signals output by the test device 4 via the signal driver devices 5a, 5b, 5c, 5d may, via the lines 7, the contact needles 9a, 9b, 9c, 9d of the semiconductor device test card 8, and the corresponding semiconductor device connections 10a, 18a, 10c, 18b, be input in the respectively desired semiconductor device 3a, 3b, 3c, 3d.

The test output signals output in reaction to the input test input signals at corresponding (e.g., the above-mentioned, or different) semiconductor device connections or at corresponding semiconductor device pads provided at the surface of the wafer (or the above-mentioned pins) are, corresponding inversely as described above with respect to the test input signals, tapped by corresponding contact needles 9a, 9b, 9c, 9d of the semiconductor device test card 8, and supplied to corresponding connections 6 of the test device 4 via the above-mentioned lines 7 (or, if the use of a probe card is waived, e.g., directly to the connections 6). In the test device 4, an evaluation of the test output signals may then take place.

In order to be able to test a large number of semiconductor devices 3a, 3b, 3c, 3d, 3e, 3f, 3g, 3h (that are, for instance, provided on one and the same wafer 2) in parallel or simultaneously and with one and the same test device 4, a test input signal output at a particular connection of the test device 4 or at a particular signal driver using the test device 4 may (e.g., by providing corresponding branch lines), simultaneously, be transmitted to n different semiconductor devices 3a, 3b, 3c, 3d (e.g., to n=4, or n=8, etc. different semiconductor devices 3a, 3b, 3c, 3d forming a test group 11a of m (e.g., m=16 or e.g., m=32, etc.) different test groups 11a, 11b of the semiconductor devices that are, for instance, provided on the wafer 2 (wherein a corresponding further test input signal output at a further connection or at a further signal driver using the test device 4 is, in a correspondingly similar manner, also transmitted, for instance, to n=4, or n=8, etc. further semiconductor devices 3e, 3f, 3g, 3h forming a further test group 11b, etc.).

The respective signal driver using the test device 4 is thus, in parallel, used for the respectively n different semiconductor devices of the respective test group 11a, 11b (“shared driver”).

In one embodiment, a test input signal output at a particular connection of the test device 4 or a particular signal driver devices (“shared driver”) of the test device 4 may also, simultaneously, be transmitted to all semiconductor devices 3a, 3b, 3c, 3d, 3e, 3f, 3g, 3h arranged on the wafer 2 (e.g., to 1 different semiconductor devices), etc.

By using the above-mentioned signal driver devices as “shared drivers” it is, for instance, possible to simultaneously test, by using test input signals provided at k different test device connections or output at k different signal driver using the test device 4 (i.e. with k different test channels), e.g., n×k (or e.g., 1×k) different semiconductor devices 3a, 3b, 3c, 3d.

In one embodiment test methods, e.g., in soft trimming methods used for setting particular, internal voltages in the semiconductor device 3a, 3b, 3c, 3d, etc., it is not possible to simultaneously use one and the same test input signal for a plurality of different, in one embodiment for all semiconductor devices 3a, 3b, 3c, 3d comprised in the respective test group 11a, 11b (or all semiconductor devices 3a, 3b, 3c, 3d arranged on the wafer 2).

Instead, the corresponding test method, e.g., the respective soft trimming method, has to be performed separately for every semiconductor device 3a, 3b, 3c, 3d (comprised in the corresponding test group 11a, 11b or on the wafer 2).

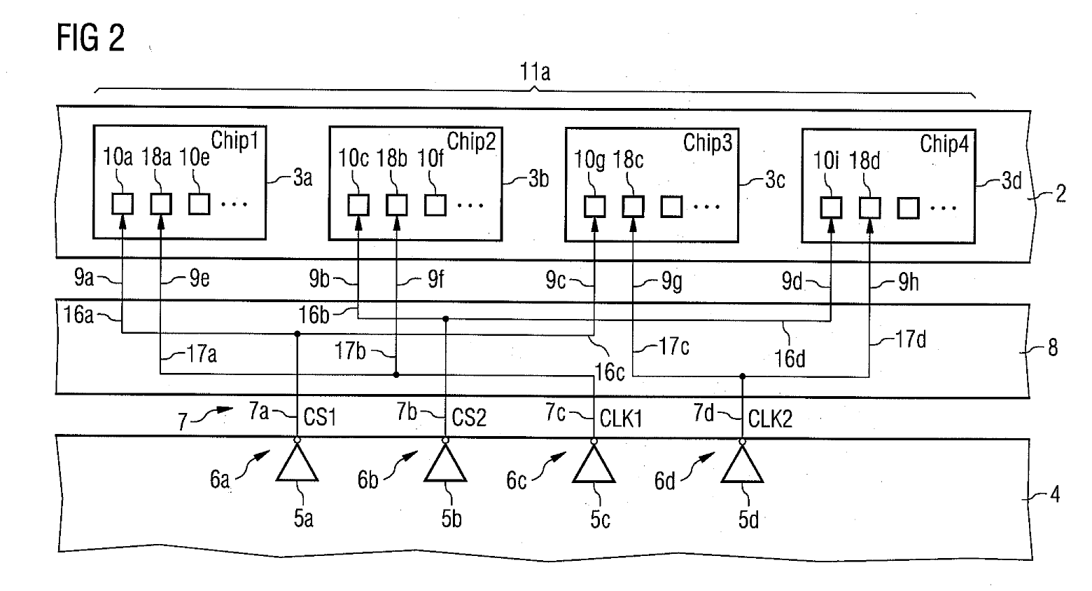

For addressing or selecting the respectively concerned semiconductor device 3a, 3b, 3c, 3d, the respective semiconductor devices 3a, 3b, 3c, 3d (and/or the semiconductor device test device 4 or the semiconductor device test card 8) according to the present embodiment may be equipped in a particular manner explained in the following by using FIG. 2, and the method explained in detail in the following may be used:

FIG. 2 illustrates, schematically and by way of example, a possible design of a section of the semiconductor device test card 8 illustrated in FIG. 1, of a section of the semiconductor device test device 4 illustrated in FIG. 1, and of a section of the wafer 2 illustrated in FIG. 1 with semiconductor devices present thereon (here: the semiconductor devices 3a, 3b, 3c, 3d comprised in the first test group 11a).

As is illustrated in FIG. 2, the semiconductor devices 3a 3b, 3c, 3d may all be structured and equipped identically or substantially identically and, as will be explained in more detail in the following, for instance, include corresponding connections 10a, 10b, used, for instance, as semiconductor device select connections or chip select connections (CS connections), at respectively identical or corresponding places.

In the present embodiment, as is illustrated in FIG. 2, every semiconductor device 3a, 3b, 3c, 3d may, for instance, include an individual corresponding chip select or CS connection (e.g., a corresponding chip select or CS pad 10a, 10b provided at the surface of the respective semiconductor device), or also a plurality of separate, different chip select connections or chip select pads.

As is further illustrated in FIG. 2, the semiconductor devices 3a, 3b, 3c, 3d may, in addition to the above-mentioned chip select connections 10a, 10c, include also in respectively identical or corresponding places, corresponding connections 18a, 18b that are, for instance, used as clock connections (CLK connections).

In the present embodiment, as is illustrated in FIG. 2, every semiconductor device 3a, 3b, 3c, 3d may, for instance, include an individual corresponding clock or CLK connection (e.g., a corresponding clock or CLK pad 18a, 18b provided at the surface of the respective semiconductor device), or also a plurality of separate, different clock connections.

As will be explained in more detail in the following, a respective connection 18a, 18b may, except as clock connection (and respectively jointly with a corresponding one of the above-mentioned (CS) connections 10a, 10c), additionally also be used for addressing or selecting a respective semiconductor device 3a, 3b, 3c, 3d (i.e. except as clock or CLK connection additionally also as “further” chip select connection 18a, 18b).

As is further illustrated in FIG. 2, the semiconductor devices 3a, 3b, 3c, 3d may, in addition to the above-mentioned chip select connections 10a, 10c and the above-mentioned clock connections 18a, 18b, also e.g., at respectively identical or corresponding places, include one or a plurality of further connections or pads 10e, 10f that may be used along with the chip select connections 10a, 10c or clock connections 18a, 18b, etc. for performing the above-mentioned test methods performed by using the test device 4.

In accordance with FIG. 2, a chip select or semiconductor device select signal CS1 possibly (cf. below) output at a corresponding connection (here: e.g., the connection 6a) of the test device 4 by a corresponding signal driver devices (here: e.g., the signal driver devices 5a) is, via a corresponding line 7a of the above-mentioned N lines 7, transmitted to the semiconductor device test card 8.

From the test card 8, the chip select or semiconductor device select signal CS1 is, as is also illustrated in FIG. 2, transmitted, via a corresponding connection line 16a provided in the test card 8, to a contact needle 9a assigned to the above-mentioned first semiconductor device 3a (“Chip1”) of the above-mentioned test group 1a, and additionally, via a corresponding further connection line 16c provided in the test card 8, to a contact needle 9c assigned to the above-mentioned third semiconductor device 3a (“Chip3”) of the above-mentioned test group 11a.

The contact needle 9a may, as is illustrated in FIG. 2, contact the chip select connection 10a of the first semiconductor device 3a which is assigned to this contact needle 9a, and the contact needle 9c may contact the chip select connection 10g of the third semiconductor device 3c which is assigned to this contact needle 9c, so that the above-mentioned chip select or semiconductor device select signal CS1 may, from the test card 8 via the chip select connection 10a, be input in the first semiconductor device 3a, and via the chip select connection 10g in the third semiconductor device 3c.

As is further illustrated in FIG. 2, a further chip select or semiconductor device select signal CS2 possibly (cf. below) output at a corresponding further connection (here: the connection 6b) of the test device 4 by a corresponding signal driver devices (here: the signal driver devices 5b) is, via a corresponding further line 7b of the above-mentioned N lines 7, transmitted to the semiconductor device test card 8.

From the test card 8, the chip select or semiconductor device select signal CS2 is, as is also illustrated in FIG. 2, transmitted via a corresponding connection line 16b provided in the test card 8 to a contact needle 9b assigned to the above-mentioned second semiconductor device 3b (“Chip2) of the above-mentioned test group 11a, and additionally via a corresponding further connection line 16d provided in the test card 8 to a contact needle 9d assigned to the above-mentioned fourth semiconductor device 3d (“Chip4”) of the above-mentioned test group 11a.

The contact needle 9b may, as is illustrated in FIG. 2, contact the chip select connection 10c of the second semiconductor device 3b which is assigned to this contact needle 9b, and the contact needle 9b may contact the chip select connection 10i of the fourth semiconductor device 3d which is assigned to this contact needle 9d, so that the above-mentioned chip select or semiconductor device select signal CS2 may be input from the test card 8 via the chip select connection 10c in the second semiconductor device 3b, and via the chip select connection 10i in the fourth semiconductor device 3d.

As is further illustrated in FIG. 2, a clock signal CLK1 possibly (cf. below) output at a corresponding connection (here: the connection 6c) of the test device 4 by a corresponding signal driver devices (here: the signal driver devices 5c) is transmitted to the semiconductor device test card 8 via a corresponding additional line 7c of the above-mentioned N lines 7.

From the test card 8, the clock signal CLK1 is, as is also illustrated in FIG. 2, via a corresponding connection line 1 7a provided in the test card 8, transmitted to a contact needle 9e assigned to the above-mentioned first semiconductor device 3a (“Chip 1”) of the above-mentioned test group 11 a, and additionally, via a corresponding further connection line 17b provided in the test card 8, to a contact needle 9f assigned to the above-mentioned second semiconductor device 3b (“Chip2”) of the above-mentioned test group 11a.

The contact needle 9e may, as is illustrated in FIG. 2, contact the clock connection 18a of the first semiconductor device 3a which is assigned to this contact needle 9e, and the contact needle 9f may contact the clock connection 18b of the second semiconductor device 3b which is assigned to this contact needle 9f, so that the above-mentioned clock signal CLK1 may be input in the first semiconductor device 3a from the test card 8 via the clock connection 18a, and in the second semiconductor device 3b via the clock connection 18b.

As is further illustrated in FIG. 2, a further clock signal CLK2 possibly (cf below) output at a corresponding connection (here: the connection 6d) of the test device 4 by a corresponding signal driver devices (here: the signal driver devices 5d) is transmitted to the semiconductor device test card 8 via a corresponding further line 7d of the above-mentioned N lines 7.

From the test card 8, the clock signal CLK2 is, as is also illustrated in FIG. 2, via a corresponding connection line 17c provided in the test card 8, transmitted to a contact needle 9g assigned to the above-mentioned third semiconductor device 3c (“Chip3”) of the above-mentioned test group 11a, and additionally, via a corresponding further connection line 17d provided in the test card 8, to a contact needle 9h assigned to the above-mentioned fourth semiconductor device 3d (“Chip4”) of the above-mentioned test group 11a.

The contact needle 9g may, as is illustrated in FIG. 2, contact the clock connection 18c of the third semiconductor device 3c which is assigned to this contact needle 9g, and the contact needle 9h may contact the clock connection 18d of the fourth semiconductor device 3d which is assigned to this contact needle 9h, so that the above-mentioned clock signal CLK2 may be input in the third semiconductor device 3c from the test card 8 via the clock connection 18c and in the fourth semiconductor device 3d via the clock connection 18d.

If, for performing a corresponding one of the above-mentioned test methods, the above-mentioned first semiconductor device 3a (“Chip1”) of the above-mentioned semiconductor devices 3a, 3b, 3c, 3d of the first test group 11a (not, however, the remaining semiconductor devices 3b, 3c, 3d of the test group 11a) are to be addressed or selected, the test device 4 (or a control device provided in the test device 4) initiates that the signal driver device 5a outputs the above-mentioned chip select or semiconductor device select signal CS1 (in that, for instance, a constant, “logic high” voltage level is applied at the output of the signal driver device 5a (or: a constant, “logic low” voltage level)), and the signal driver device 5c the above-mentioned clock signal CLK1 (in that, for instance, a “logic high” and a “logic low” voltage level is alternately applied at the output of the signal driver device 5c).

Contrary to this, the signal driver device 5b does not output any chip select signal CS2 (in that, for instance, the output of the signal driver device 5b is constantly kept at the above-mentioned “logic low” (or “logic high”) voltage level), and the signal driver device 5d does not output any clock signal CLK2 (in that, for instance, the output of the signal driver device 5d is constantly kept at the above-mentioned “logic low” (or “logic high”) voltage level).

If, instead of the above-mentioned first, the above-mentioned second semiconductor device 3b (“Chip2”) of the above-mentioned semiconductor devices 3a, 3b, 3c, 3d of the first test group 11a (not, however, the remaining semiconductor devices 3a, 3c, 3d of the test group 11a) are to be addressed or selected, the test device 4 (or the above-mentioned control device) initiates that the above-mentioned chip select or semiconductor device select signal CS2 is output by the signal driver device 5b (in that, for instance, a constant, “logic high” voltage level is applied at the output of the signal driver device 5b (or: a constant, “logic low” voltage level)), and the above-mentioned clock signal CLK1 by the signal driver device 5c (in that, for instance, a “logic high” and a “logic low” voltage level are alternately applied at the output of the signal driver device 5c).

Contrary to this, the signal driver device 5a does not output any chip select signal CS1 (in that, for instance, the output of the signal driver device 5a is constantly kept at the above-mentioned “logic low” (or “logic high”) voltage level), and the signal driver device 5d does not output any clock signal CLK2 (in that, for instance, the output of the signal driver device 5d is kept constantly at the above-mentioned “logic low” (or “logic high”) voltage level).

If, instead, the above-mentioned third semiconductor device 3c (“Chip3”) of the above-mentioned semiconductor devices 3a, 3b, 3c, 3d of the first test group 11a (not, however, the remaining semiconductor devices 3a, 3b, 3d of the test group 11a) are to be addressed or selected, the test device 4 (or the above-mentioned control device) initiates that the signal driver device 5a outputs the above-mentioned chip select or semiconductor device select signal CS1 (in that, for instance, a constant, “logic high” voltage level is applied at the output of the signal driver device 5a (or: a constant, “logic low” voltage level)), and the signal driver device 5d the above-mentioned clock signal CLK2 (in that, for instance, a “logic high” and a “logic low” voltage level are alternately applied at the output of the signal driver device 5d).

Contrary to this, the signal driver device 5b does not output any chip select signal CS2 (in that, for instance, the output of the signal driver device 5b is kept constantly at the above-mentioned “logic low” (or “logic high”) voltage level, and the signal driver device 5c does not output any clock signal CLK1 (in that, for instance, the output of the signal driver device 5c is kept constantly at the above-mentioned “logic low” (or “logic high”) voltage level).

If, instead, the above-mentioned fourth semiconductor device 3d (“Chip4”) of the above-mentioned semiconductor devices 3a, 3b, 3c, 3d of the first test group 11a (not, however, the remaining semiconductor devices 3a, 3b, 3c of the test group 11a) are to be addressed or selected, the test device 4 (or the above-mentioned control device) initiates that the signal driver device 5b outputs the above-mentioned chip select or semiconductor device select signal CS2 (in that, for instance, a constant, “logic high” voltage level is applied at the output of the signal driver device 5b (or alternatively: a constant, “logic low” voltage level)), and the signal driver device 5d the above-mentioned clock signal CLK2 (in that, for instance, a “logic high” and a “logic low” voltage level are alternately applied at the output of the signal driver device 5d).

Contrary to this, the signal driver device 5a does not output any chip select signal CS 1 (in that, for instance, the output of the signal driver device 5a is kept constantly at the above-mentioned “logic low” (or “logic high”) voltage level, and the signal driver device 5c does not output any clock signal CLK1 (in that, for instance, the output of the signal driver device 5c is kept constantly at the above-mentioned “logic low” (or “logic high”) voltage level).

Every semiconductor device 3a, 3b, 3c, 3d includes control device by which it is determined whether the respective semiconductor device 3a, 3b, 3c, 3d was addressed or selected to perform one of the above-mentioned test methods, or not.

Only if, at the respective semiconductor device 3a, 3b, 3c, 3d, both at the respective chip select connection 10a, 10c, 10g, 10i a corresponding chip select or semiconductor device select signal CS1 or CS2 is present (e.g., the above-mentioned “logic high” voltage level (or alternatively: the above-mentioned “logic low” voltage level)), and at the respective clock connection 18a, 18b, 18c, 18d a corresponding clock signal CLK1 or CLK2 (e.g., alternately the above-mentioned “logic high” and “logic low” voltage level) is present, does the control device of the respective semiconductor device 3a, 3b, 3c, 3d detect that the corresponding semiconductor device 3a, 3b, 3c, 3d was addressed or selected to perform one of the above-mentioned test methods.

If, contrary to this, either at the respective chip select connection 10a, 10c, 10g, 10i no corresponding chip select or semiconductor device select signal CS1 or CS2 is present, or at the respective clock connection 18a, 18b, 18c, 18d no corresponding clock signal CLK1 or CLK2 is present, or neither at the respective chip select connection 10a, 10c, 10g, 10i a corresponding chip select or semiconductor device select signal CS1 or CS2, nor at the respective clock connection 18a, 18b, 18c, 18d a corresponding clock signal CLK1 or CLK2 is present, the control device of the respective semiconductor device 3a, 3b, 3c, 3d detects that the corresponding semiconductor device 3a, 3b, 3c, 3d was not addressed or selected to perform one of the above-mentioned test methods. The respective control means may if no corresponding clock signal CLK1 or CLK2 is present at the respective clock connection 18a, 18b, 18c, 18d, remain deactivated exactly due to the non-presence of this signal, so that, “implicitly”, the respective control means detects a non-addressing or non-selecting of the corresponding semiconductor device 3a, 3b, 3c, 3d.

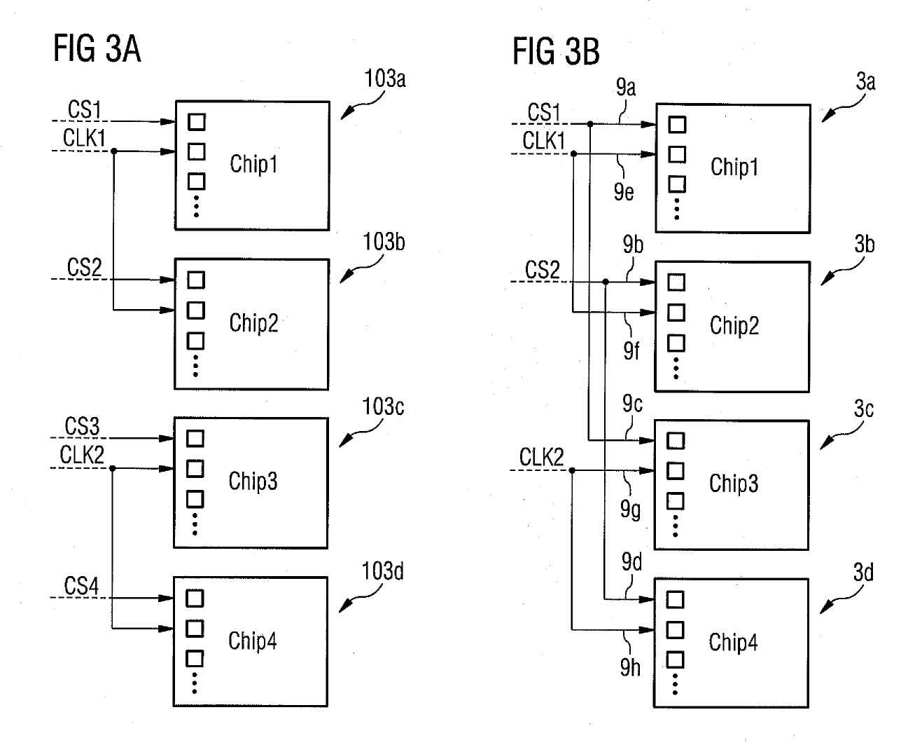

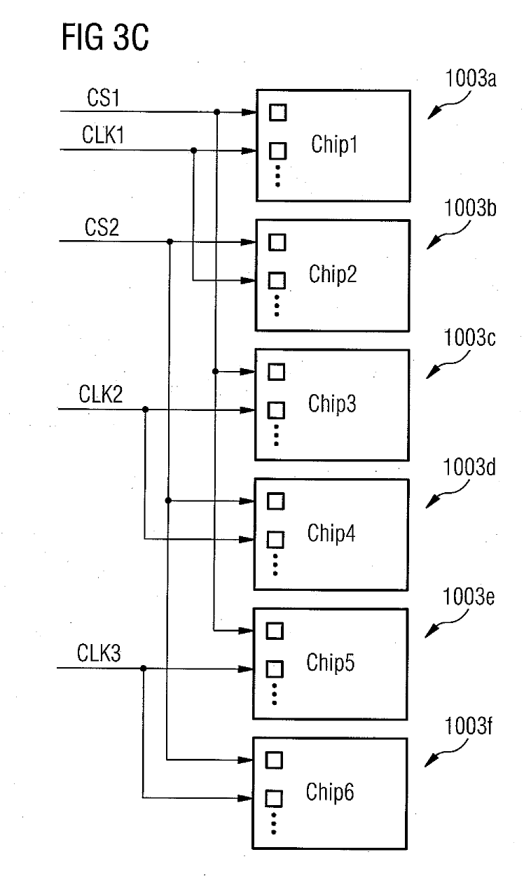

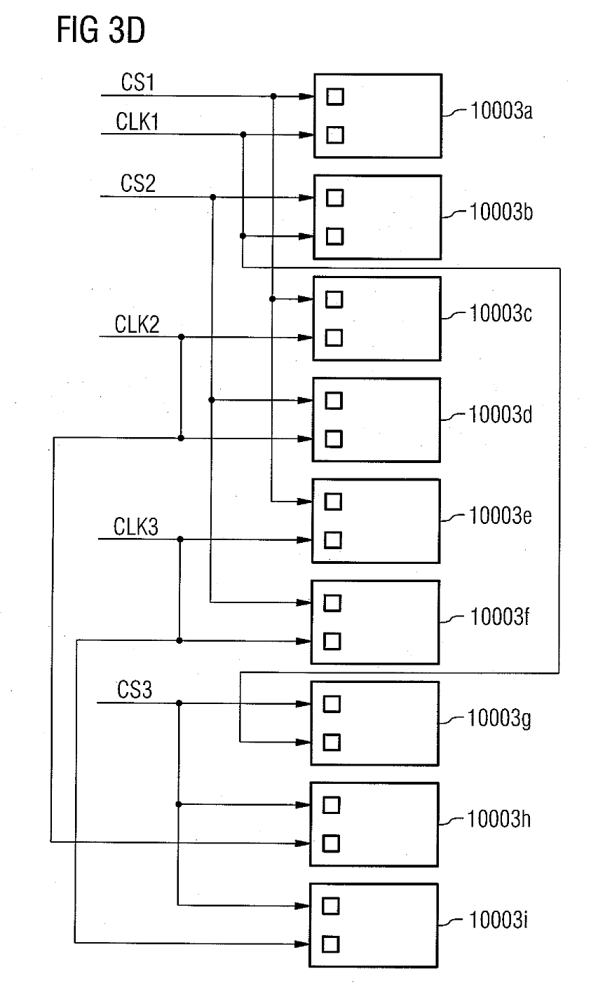

In other words, as results, for instance, also from FIG. 3b, for selecting or addressing the first semiconductor device 3a (“Chip1”), the above-mentioned chip select or semiconductor device select signal CS1 and the above-mentioned clock signal CLK1 are activated during a corresponding “chip select phase” of the respective test method. Contrary to this, for selecting or addressing the first semiconductor device 3a (“Chip1”), the above-mentioned chip select or semiconductor device select signal CS2 and the above-mentioned clock signal CLK2 remain in a deactivated state.

Correspondingly similar, as results also, for instance, from FIG. 3b, for selecting or addressing the second semiconductor device 3b (“Chip2”), the above-mentioned chip select or semiconductor device select signal CS2 and the above-mentioned clock signal CLK1 are activated during the above-mentioned “chip select phase”. Contrary to this, for selecting or addressing the second semiconductor device 3b (“Chip2”), the above-mentioned chip select or semiconductor device select signal CS1 and the above-mentioned clock signal CLK2 remain in a deactivated state.

Furthermore, for selecting or addressing the third semiconductor device 3c (“Chip3”), the above-mentioned chip select or semiconductor device select signal CS1 and the above-mentioned clock signal CLK2 are activated whereas the above-mentioned chip select or semiconductor device select signal CS2 and the above-mentioned clock signal CLK1 remain in a deactivated state, and for selecting or addressing the fourth semiconductor device 3d (“Chip4”), the above-mentioned chip select or semiconductor device select signal CS2 and the above-mentioned clock signal CLK2 are activated whereas the above-mentioned chip select or semiconductor device select signal CS1 and the above-mentioned clock signal CLK1 remain in a deactivated state.

Due to this “matrix-like” selection or addressing of the respective semiconductor device by using the above-mentioned chip select or semiconductor device select signals CS1, CS2 and the above-mentioned clock signals CLK1, CLK2 it is possible that only relatively few additional separate test channels (here: the two above-mentioned CS channels CS1, CS2) are required for selecting or addressing, in one embodiment e.g., a number of separate, additionally necessary test channels which is smaller than the number of semiconductor devices that is selectable with them.

Contrary to this, as results, for instance, from FIG. 3a, in the case of conventional methods for selecting or addressing a first semiconductor device 103a (“Chip1”) of e.g., four semiconductor devices, a first chip select or semiconductor device select signal CS1 separately assigned to the first semiconductor device 103a is, for instance, activated, for selecting or addressing a second semiconductor device 103b (“Chip2”), a second chip select or semiconductor device select signal CS2 separately assigned to the second semiconductor device 103b, for selecting or addressing a third semiconductor device 103c (“Chip3”), a third chip select or semiconductor device select signal CS3 separately assigned to the third semiconductor device 103c, and for selecting or addressing a fourth semiconductor device 103d (“Chip4”), a fourth chip select or semiconductor device select signal CS4 separately assigned to the fourth semiconductor device 103d.

In conventional methods, the number of separate test channels required for selecting or addressing semiconductor devices 103a, 103b, 103c, 103d may thus be equal to the number of semiconductor devices selectable with them, i.e. be relatively large.

In variants of the embodiments described above using FIGS. 1, 2, 3b there may, as already mentioned, also include more (or less) than four semiconductor devices in a corresponding test group 11a, 11b, e.g., six, eight, nine, or sixteen semiconductor devices, etc.

For selecting or addressing the respective semiconductor device of the group, correspondingly more signals or more (additional) test channels may then, for instance, be used than described above by using FIGS. 1, 2, 3b, e.g., apart from the above-mentioned two chip select or semiconductor device select signals or channels CS1, CS2 or corresponding or correspondingly similar chip select signals or channels, one or more further chip select signals or channels, and/or apart from the above-mentioned clock signals or channels CLK1, CLK2 or corresponding or correspondingly similar clock signals or channels, one or a more further clock signals or channels, etc.

For instance, a test group may include, in addition to the above-mentioned four semiconductor devices 3a, 3b, 3c, 3d, two more devices, wherein a first one of the further devices is, for instance, connected to the above-mentioned clock channel CLK1, and a second one of the further devices, for instance, to the above-mentioned clock channel CLK2, and both further devices jointly to an, additional, chip select channel CS3. For selecting or addressing the first further semiconductor device, a corresponding chip select signal CS3 may, for instance, be applied or activated at the additional chip select channel CS3, and additionally at the clock channel CLK1 the above-mentioned clock signal CLK1, whereas the above-mentioned chip select signals CS1, CS2 and the above-mentioned clock signal CLK2 remain in a deactivated state. Correspondingly, for selecting or addressing the second further semiconductor device, the above-mentioned chip select signal CS3 may, for instance, be applied or activated at the additional chip select channel CS3, and additionally the above-mentioned clock signal CLK2 at the clock channel CLK2, whereas the above-mentioned chip select signals CS1, CS2 and the above-mentioned clock signal CLK1 remain in a deactivated state, etc., etc.

In a further alternative embodiment, a test group, as illustrated in FIG. 3c, may, as described above, include, for instance, six semiconductor devices 1003a, 1003b, 1003c, 1003d, 1003e, 1003f, wherein a first semiconductor device 1003a, in one embodiment the chip select connection thereof, may, however, be connected to a chip select channel CS1, as illustrated in FIG. 3c, likewise a third semiconductor device 1003c, in one embodiment the chip select connection thereof, and a fifth semiconductor device 1003e, in one embodiment the chip select connection thereof.

Furthermore, a second semiconductor device 1003b, in one embodiment the chip select connection thereof may be connected to a chip select channel CS2, likewise a fourth semiconductor device 1003d, in one embodiment the chip select connection thereof, and a sixth semiconductor device 1003f, in one embodiment the chip select connection thereof.

Moreover, as is also illustrated in FIG. 3c, the first semiconductor device 1003, in one embodiment the clock connection thereof, may be connected to a clock channel CLK1, likewise the second semiconductor device 1003b, in one embodiment the clock connection thereof.

Additionally, as is also illustrated in FIG. 3c, the third semiconductor device 1003c, in one embodiment the clock connection thereof, may be connected to a clock channel CLK2, likewise the fourth semiconductor device 1003d, in one embodiment the clock connection thereof, and the fifth semiconductor device 1003e, in one embodiment the clock connection thereof, may be connected to a clock channel CLK3, likewise the sixth semiconductor device 1003f, in one embodiment the clock connection thereof.

For selecting or addressing the first semiconductor device 1003a, a corresponding chip select signal CS1 may, for instance, be applied or activated at the chip select channel CS1, and additionally at the clock channel CLK1 a clock signal CLK1, whereas the above-mentioned chip select signal CS2 and the above-mentioned clock signals CLK2, CLK3 remain in a deactivated state. Correspondingly, for selecting or addressing the second semiconductor device 1003b, a corresponding chip select signal CS2 may, for instance, be applied or activated at the chip select channel CS2, and additionally at the clock channel CLK1 a clock signal CLK1, whereas the above-mentioned chip select signal CS1 and the above-mentioned clock signals CLK2, CLK3 remain in a deactivated state. Furthermore, for selecting or addressing the third semiconductor device 1003c, a corresponding chip select signal CS1 may, for instance, be applied or activated at the chip select channel CS1, and additionally at the clock channel CLK2 a clock signal CLK2, whereas the above-mentioned chip select signal CS2 and the above-mentioned clock signals CLK1, CLK3 remain in a deactivated state. Additionally, for selecting or addressing the fourth semiconductor device 1003d, a corresponding chip select signal CS2 may, for instance, be applied or activated at the chip select channel CS2, and additionally at the clock channel CLK2 a clock signal CLK2, whereas the above-mentioned chip select signal CS1 and the above-mentioned clock signals CLK1, CLK3 remain in a deactivated state. Furthermore, for selecting or addressing the fifth semiconductor device 1003e, a corresponding chip select signal CS1 may, for instance, be applied or activated at the chip select channel CS1, and additionally at the clock channel CLK3 a clock signal CLK3, whereas the above-mentioned chip select signal CS2 and the above-mentioned clock signals CLK1, CLK2 remain in a deactivated state. Additionally, for selecting or addressing the sixth semiconductor device 1003f, a corresponding chip select signal CS2 may, for instance, be applied or activated at the chip select channel CS2, and additionally at the clock channel CLK3 a clock signal CLK3, whereas the above-mentioned chip select signal CS1 and the above-mentioned clock signals CLK1, CLK2 remain in a deactivated state.

In an additional alternative embodiment, a test group, as is illustrated in FIG. 3d, may, for instance, include nine semiconductor devices 10003a, 10003b, 10003c, 10003d, 10003e, 10003f.

A first semiconductor device 10003a, in one embodiment the chip select connection thereof, may, as is illustrated in FIG. 3d, be connected to a chip select channel CS1, likewise a third semiconductor device 10003c, in one embodiment the chip select connection thereof, and a fifth semiconductor device 10003e, in one embodiment the chip select connection thereof.

Furthermore, a second semiconductor device 10003b, in one embodiment the chip select connection thereof, may be connected to a chip select channel CS2, likewise a fourth semiconductor device 10003d, in one embodiment the chip select connection thereof, and a sixth semiconductor device 10003f, in one embodiment the chip select connection thereof.

Additionally, a seventh semiconductor device 10003g, in one embodiment the chip select connection thereof, may be connected to a chip select channel CS3, likewise an eighth semiconductor device 10003h, in one embodiment the chip select connection thereof, and a ninth semiconductor device 10003i, in one embodiment the chip select connection thereof.

Moreover, as is also illustrated in FIG. 3d, the first semiconductor device 10003a, in one embodiment the clock connection thereof, may be connected to a clock channel CLK1, likewise the second semiconductor device 10003b, in one embodiment the clock connection thereof, and the seventh semiconductor device 10003g, in one embodiment the clock connection thereof.

Additionally, as is also illustrated in FIG. 3d, the third semiconductor device 10003c, in one embodiment the clock connection thereof, may be connected to a clock channel CLK2, likewise the fourth semiconductor device 10003d, in one embodiment the clock connection thereof, and the eighth semiconductor device 10003h, in one embodiment the clock connection thereof.

Furthermore, the fifth semiconductor device 10003e, in one embodiment the clock connection thereof, may be connected to a clock channel CLK3, likewise the sixth semiconductor device 10003f, in one embodiment the clock connection thereof, and the ninth semiconductor device 10003i, in one embodiment the clock connection thereof.

For selecting or addressing, for instance, the seventh semiconductor device 10003g, a corresponding chip select signal CS3 may, for instance, be applied or activated at the chip select channel CS3, and additionally at the clock channel CLK1 a clock signal CLK1, whereas the above-mentioned chip select signals CS1, CS2 and the above-mentioned clock signals CLK2, CLK3 remain in a deactivated state. Correspondingly, for selecting or addressing the eighth semiconductor device 10003h, a corresponding chip select signal CS3 may, for instance, be applied or activated at the chip select channel CS3, and additionally at the clock channel CLK2 a clock signal CLK2, whereas the above-mentioned chip select signals CS1, CS2 and the above-mentioned clock signals CLK1, CLK3 remain in a deactivated state. Furthermore, for selecting or addressing the ninth semiconductor device 10003i, a corresponding chip select signal CS3 may, for instance, be applied or activated at the chip select channel CS3, and additionally at the clock channel CLK3 a clock signal CLK3, whereas the above-mentioned chip select signals CS1, CS2 and the above-mentioned clock signals CLK1, CLK2 remain in a deactivated state. The first to sixth semiconductor devices 10003a, 10003b, 10003c, 10003d, 10003e, 10003f are selected or addressed correspondingly as the first to sixth semiconductor devices 1003a, 1003b, 1003c, 1003d, 1003e, 1003f illustrated in FIG. 3c, and as explained above with respect to FIG. 3c.

In the present embodiments, in one embodiment, for instance, in the embodiments illustrated by using FIGS. 1, 2, and 3b, and the above-mentioned further embodiments, a correspondingly conventional device test method may be performed following the above-mentioned “chip select phase” for the semiconductor device selected or addressed in the above-mentioned manner. In the course of this test method (“test phase”), the respective signal driver means 5c, 5d of the test device 4 may continue to output or again output the above-mentioned clock signal CLK1 or CLK2, and it may thus be i.a. supplied to the respective clock connection 18a, 18b, 18c, 18d of the respectively selected or addressed semiconductor device.

During the “test phase”, the clock signal CLK1 or CLK2 may then, other than during the “chip select phase”, no longer be used for semiconductor device selection or addressing, but as a usual clock signal, in one embodiment, for instance, for controlling the time coordination of the signal relay or output in the corresponding semiconductor device respectively selected or addressed during the “chip select phase”.

Alternatively to the “shared driver” semiconductor devices 3a, 3b, etc. that have been described by way of example above, or to corresponding devices that receive corresponding joint or shared signals in a corresponding test phase anyway, the above-mentioned selection or addressing method or a correspondingly similar method may, for a corresponding chip select phase preceding the test phase, also be used with any other semiconductor devices, e.g., with devices that are otherwise, in one embodiment during the test phase, independent of each other or do not receive any corresponding shared signals, or devices that belong to orthogonal shared driver groups, etc.

Although specific embodiments have been illustrated and described herein, it will be appreciated by those of ordinary skill in the art that a variety of alternate and/or equivalent implementations may be substituted for the specific embodiments shown and described without departing from the scope of the present invention. This application is intended to cover any adaptations or variations of the specific embodiments discussed herein. Therefore, it is intended that this invention be limited only by the claims and the equivalents thereof.

What is claimed is:

1. A semiconductor device test system comprising:
a plurality of semiconductor devices to be tested which form a group of semiconductor devices to be tested; and
wherein, for addressing or selecting one of the semiconductor devices of the group, at least two signals are used which are supplied to the respective semiconductor device to be addressed or selected via at least two different semiconductor device connections.

2. The system of claim 1, including wherein, with n different signals, up to (n−1)+2ⁿ⁻⁴ semiconductor devices to be tested are addressed or selected, wherein n is an integer and is greater than or equal to 4.

3. The system of claim 1, comprising a device configured such that the device supplies a first signal to a first and a third one of the semiconductor devices, a second signal to a second and a fourth one of the semiconductor devices, a third signal to the first and the second ones of the semiconductor devices, and a fourth signal to the third and the fourth ones of the semiconductor devices.

4. The system of claim 3, comprising a test device for activating the first and third signals if the first one of the semiconductor devices is to be addressed or selected.

5. The system of claim 4, wherein the device comprises a first input connection for receiving the first signal from the test device which is connected with two corresponding output connections of the device for supplying the first signal to the first and third ones of the semiconductor devices.

6. The system of claim 4, wherein the device comprises a second input connection for receiving the second signal from the test device, which is connected with two corresponding output connections of the device for supplying the second signal to the second and fourth ones of the semiconductor devices.

7. The system of claim 4, wherein the device comprises a third input connection for receiving the third signal from the test device, which is connected with two corresponding output connections of the device for supplying the third signal to the first and the second ones of the semiconductor devices.

8. The system of claim 4, wherein the device comprises a fourth input connection for receiving the fourth signal from the test device, which is connected with two corresponding output connections of the device for supplying the fourth signal to the third and the fourth ones of the semiconductor devices.

9. The system of claim 3, comprising a test device for activating the first and fourth signals if the third one of the semiconductor devices is to be addressed or selected.

10. The system of claim 3, comprising a test device for activating the second and third signals if the second one of the semiconductor devices is to be addressed or selected.

11. The system of claim 3, comprising a test device for activating the second and fourth signals if the fourth one of the semiconductor devices is to be addressed or selected.

12. The system of claim 3, wherein the device comprises a test card or probe card.

13. The system of claim 3, comprising wherein the first and/or second signal(s) is/are used exclusively for semiconductor device addressing or selection.

14. The system of claim 3, comprising wherein the third and/or fourth signal(s) is/are used for one or several further functions except for semiconductor device addressing or selection.

15. The system of claim 14, comprising wherein the third and/or fourth signal(s) is/are used as clock signal(s) except for semiconductor device addressing or selection.

16. The system of claim 1, comprising wherein the semiconductor devices are arranged on one and the same wafer.

17. The system of claim 1, comprising wherein the semiconductor devices are memory devices.

18. The system of claim 17, comprising wherein the memory devices are RAMs, in particular DRAMs.

19. A method for testing semiconductor devices comprising
forming a group of semiconductor devices to be tested; and
supplying at least two different signals, for addressing or selecting one of the semiconductor devices of the group, to the respective semiconductor device to be addressed or selected via at least two different semiconductor device connections.

20. The method of claim 19, comprising:
activating a first and a third signal if a first one of the semiconductor devices is to be addressed or selected.

21. The method of claim 20, comprising:
activating the first and a fourth signal if a third one of the semiconductor devices is to be addressed or selected.

22. The method of claim 21, comprising:
activating a second and the third signal if a second one of the semiconductor devices is to be addressed or selected.

23. The method of claim 22, comprising:
activating the second and the fourth signals if a fourth one of the semiconductor devices is to be addressed or selected.

24. A semiconductor device test card comprising:
a first input connection for receiving a first signal from a test device, which is connected with two corresponding test card output connections for supplying the first signal to a first and a third semiconductor device;
a second input connection for receiving a second signal from the test device, which is connected with two corresponding test card output connections for supplying the second signal to a second and a fourth semiconductor device;
a third input connection for receiving a third signal from the test device, which is connected with two corresponding test card output connections for supplying the third signal to the first and second semiconductor devices; and
a fourth input connection for receiving a fourth signal from the test device, which is connected with two corresponding output connections for supplying the fourth signal to the third and fourth semiconductor devices.

25. A semiconductor device test device comprising:
means for activating a first and a third signal if a first one of a plurality of semiconductor devices is to be addressed or selected;
means for activating the first and a fourth signal if a third one of the semiconductor devices is to be addressed or selected;
means for activating a second and the third signal if a second one of the semiconductor devices is to be addressed or selected; and
means for activating the second and the fourth signals if a fourth one of the semiconductor devices is to be addressed or selected.
